(19) United States
(12) Patent Application Publication
(10) Pub. No.: US 2026/0161839 A1
(43) Pub. Date: Jun. 11, 2026

(54) VEHICLE BODY CLEARANCE MEASUREMENT SUPPORT SYSTEM AND VEHICLE BODY CLEARANCE MEASUREMENT SUPPORT METHOD

(71) Applicant: TOYOTA JIDOSHA KABUSHIKI KAISHA, Toyota-shi (JP)

(72) Inventors: Mei NAGATA, Nagoya-shi (JP); Yusuke Kobayashi, Toyota-shi (JP)

(73) Assignee: TOYOTA JIDOSHA KABUSHIKI KAISHA, Toyota-shi (JP)

(21) Appl. No.: 19/393,963

(22) Filed: Nov. 19, 2025

(30) Foreign Application Priority Data
Dec. 5, 2024 (JP) 2024-212539

(51) Int. Cl. G06F 30/15

(52) U.S. Cl. CPC G06F 30/15

(57) ABSTRACT

A vehicle body clearance measurement support system includes a model provider configured to provide a CAD model, a converter configured to convert information including a design value of a clearance into a format of digitally-processable data, an integrated output unit configured to associate the CAD model provided from the model provider, the data converted by the converter into data that can be digitally processed, and a shot diagram of the CAD of a clearance to be measured, and output position information and design value information of the clearance to be measured, and a display unit configured to perform an AR display based on the information input from the integrated output unit.

### CROSS-REFERENCE TO RELATED APPLICATION

This application claims priority to Japanese Patent Application No. 2024-212539 filed on Dec. 5, 2024. The disclosure of the above-identified application, including the specification, drawings, and claims, is incorporated by reference herein in its entirety.

### BACKGROUND

### 1. Technical Field

The present disclosure relates to a vehicle body clearance measurement support system and a vehicle body clearance measurement support method.

### 2. Description of Related Art

In automobile production, a quality check is performed. As one of steps of the quality check, there is work of plate clearance measurement for measuring the size of a clearance of an overlapping portion of vehicle body parts in order to reduce a quality defect such as water leakage.

As related art, there is a method of transmitting a specific AR content from a content management server that stores AR contents to a mobile device. The AR content includes a work item for specifying work for an external device and a standard measured value of a measurable measured value for the work item.

### SUMMARY

In general, as a work method for finding a clearance, a method is adopted that includes, for each clearance, confirming a shot diagram of a CAD around the clearance to be measured, comparing the shot diagram of the CAD with an actual vehicle, and specifying the place of the clearance. However, with solely the shot diagram of the CAD in a small range around the clearance, it is difficult to specify the place to be measured from the entirety of the vehicle, and there is a problem that work takes time.

The present disclosure provides a vehicle body clearance measurement support system and a vehicle body clearance measurement support method that allow shortening a work time of an operator by enabling confirmation of a position or information of a clearance to be measured, using augmented reality (AR).

A vehicle body clearance measurement support system according to the present disclosure is a vehicle body clearance measurement support system that supports an operator in measuring a clearance of an overlapping portion of vehicle body parts. The vehicle body clearance measurement support system includes:
a model provider configured to provide a CAD model,
a converter configured to convert information including a design value of the clearance into a format of digitally-processable data, and
an integrated output unit configured to associate the CAD model provided from the model provider, the digitally-processable data converted by the converter, and a shot diagram of a CAD of the clearance to be measured, and output position information of the clearance to be measured and the information of the design value.
   As a result, the clearance information can be displayed using AR at an appropriate position on the vehicle body.

In addition, a vehicle body clearance measurement support method according to the present disclosure includes
converting information including a design value of a clearance into a format of digitally-processable data, and
associating a CAD model, the digitally-processable data in the converting, and a shot diagram of a CAD of the clearance to be measured, and outputting position information of the clearance to be measured and the information of the design value.
   As a result, the clearance information can be displayed using AR at an appropriate position on the vehicle body.

According to the present disclosure, it is possible to provide a vehicle body clearance measurement support system and a vehicle body clearance measurement support method that allow shortening the work time of the operator by enabling the confirmation of the position or information of the clearance to be measured using AR.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram showing an example of a configuration of a vehicle body clearance measurement support system according to Embodiment 1;

FIG. 2 is a diagram showing an example of a report and an example of data converted by a converter, which are output by a clearance information output unit according to Embodiment 1;

FIG. 3 is a diagram showing a state in which the position of the clearance is displayed by integrating the CAD model according to the Embodiment 1 and the data input from the converter;

FIG. 4 is a diagram showing a state in which the position of the clearance is displayed by integrating the CAD model according to the Embodiment 1 and the data input from the converter; and

FIG. 5 is a diagram showing an example of a state in which the clearance information needed for the measurement according to the Embodiment 1 is displayed using AR in accordance with the target vehicle.

### DETAILED DESCRIPTION OF EMBODIMENTS

### Embodiment 1

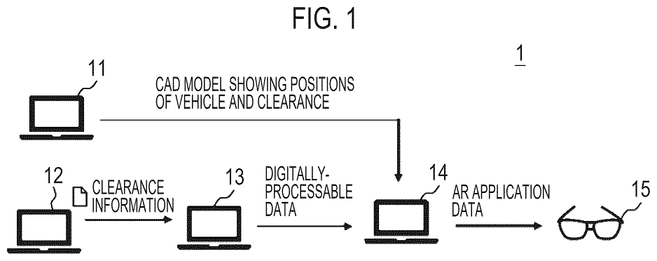

Hereinafter, a configuration of a vehicle body clearance measurement support system according to the present embodiment will be described with reference to the drawings. FIG. 1 is a diagram showing an example of a configuration of a vehicle body clearance measurement support system. In the following, the clearance is described as a clearance between the overlapping portions of the vehicle body parts.

As shown in FIG. 1, the vehicle body clearance measurement support system 1 includes a model provider 11, a clearance information output unit 12, a converter 13, an integrated output unit 14, and a display unit (AR glasses) 15.

The model provider 11 supplies a computer-aided design (CAD) model indicating the position of the vehicle and the clearance to the integrated output unit 14.

The clearance information output unit 12 outputs the report data in which the clearance information used in practice is described to the converter 13. Here, the report data output by the clearance information output unit 12 is data of an Excel report created by Excel.

The converter 13 converts the data of the Excel report input from the clearance information output unit 12, which includes the information on the design value of the clearance, into a format of digitally-processable data, and outputs the data to the integrated output unit 14. In the converter 13, the format of data can be changed by executing a program for conversion.

More specifically, in the converter 13, the format of data of the Excel report can be changed to a format of easily digitally-processable data in the output unit by executing an Excel macro that is created in advance and changes the data.

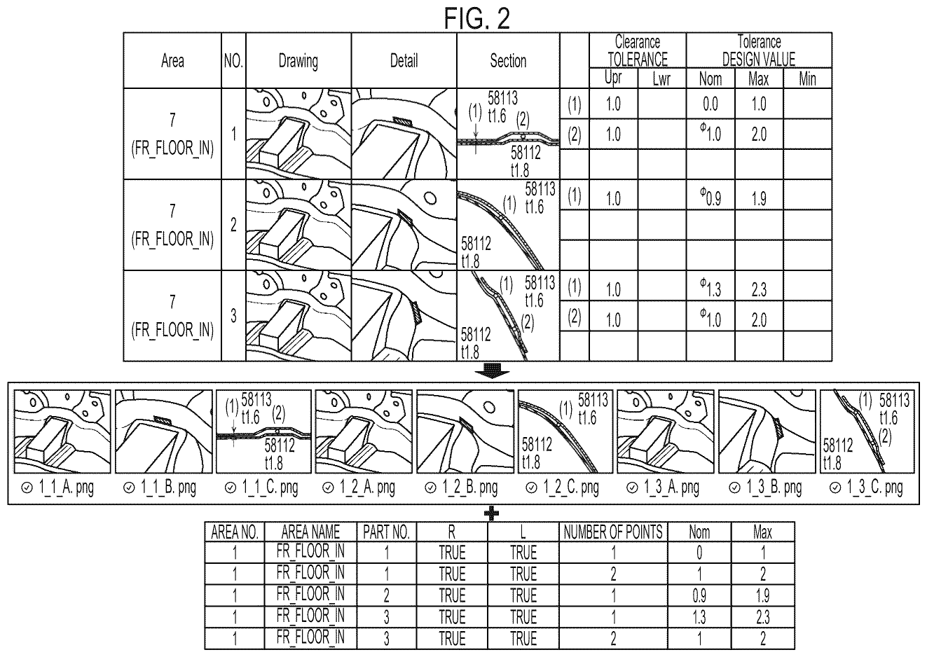

FIG. 2 is a diagram showing an example of an Excel report output by the clearance information output unit 12 and an example of data converted by the converter 13.

As shown at the top of FIG. 2, the Excel report output from the clearance information output unit 12 has images of the shot diagram and the design diagram of the CAD around the clearance, a detailed image of the clearance periphery, and an image representing the state of the clearance pasted thereon. In addition, the Excel report output from the clearance information output unit 12 includes information on an area in which a clearance is generated in the vehicle, information on a consecutive number, a tolerance, a design value, and the like. The information described in the Excel report is not limited thereto.

As shown in the center of FIG. 2 and the bottom of FIG. 2, the converter 13 changes the format and splits the Excel report input from the clearance information output unit 12. As a specific example, the converter 13 extracts a shot diagram of the CAD pasted in an Excel report. In addition, the converter 13 extracts information needed for measurement to generate a setting file described in a comma-separated values (csv) format or the like.

Here, the file set by the converter 13 is set as an output of a csv file, which is text data in which each item is separated by a comma, but is not limited to the format as long as the data is in a format that can be handled by the integrated output unit 14.

The integrated output unit 14 associates and integrates the CAD model indicating the position of the vehicle and the clearance input from the model provider 11 and the data input from the converter 13. Here, the integrated output unit 14 can use a game engine. The integrated output unit 14 outputs the information of the AR application data created by integrating to the AR glasses 15.

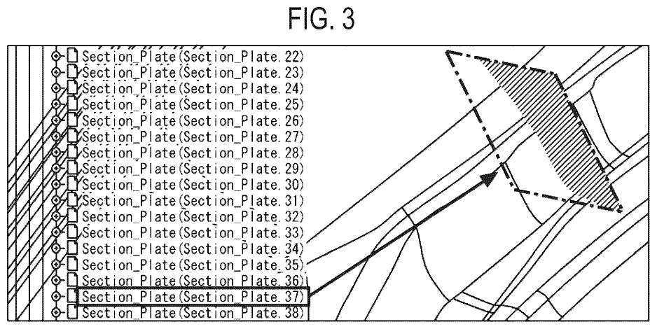

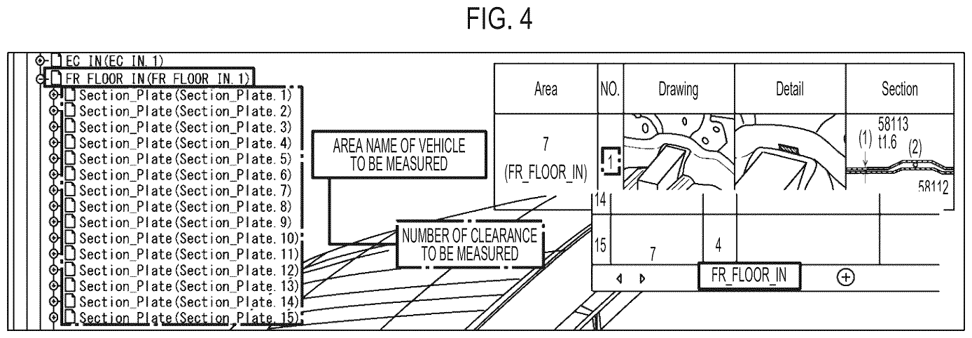

FIGS. 3 and 4 are examples of CAD data indicating the position of the clearance, in which the integrated output unit 14 integrates the CAD model input from the converter 13 and the data input from the converter 13.

On the left side of the screen shown in FIG. 3, the clearances to be measured are shown, and each clearance is numbered. When the user selects the clearance to be measured, the CAD data indicating the clearance to be measured on the panel on the right side of FIG. 3 can be displayed.

As shown in FIG. 4, the clearances to be selected shown on the left side of FIG. 3 are described as a plurality of child nodes belonging to one parent node in the tree structure. Here, as a naming rule for each node in the tree structure, the name of the vehicle area to be measured is described in the parent node, and as described above, the number of each clearance to be measured is described in the child node.

Therefore, as shown in FIG. 4, the integrated output unit 14 is in a state where the CAD data and the information on each clearance on the Excel report are associated. In other words, in the structure tree, the name of the parent node is the name of the area of the vehicle to be measured, and is “Fr_FLOOR_IN” that is front, floor, and inside. As the child node belonging to “Fr_FLOOR_IN” of the parent node, a number is assigned in “Fr_FLOOR_IN”. The integrated output unit 14 can output the information to the AR glasses 15 as the AR application data.

The AR glasses 15 are a display unit that performs the AR display based on the information input from the integrated output unit 14.

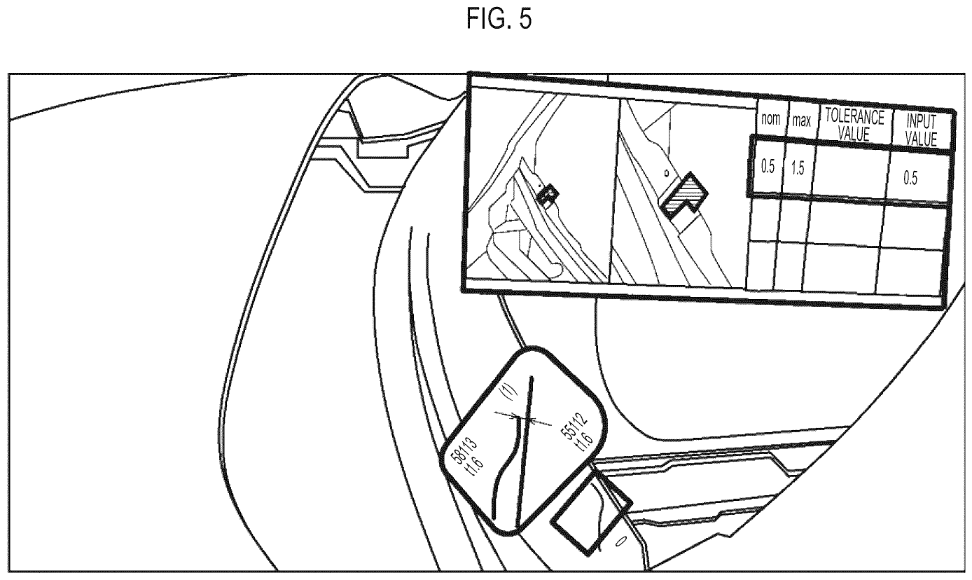

Here, FIG. 5 shows a state in which the AR glasses 15 display is performed based on the AR application data input from the integrated output unit 14. That is, FIG. 5 is an example of a viewpoint from the operator wearing the AR glasses 15, and is in a state where the AR glasses 15 performs an AR display on the clearance information needed for the measurement in accordance with the target vehicle.

In this way, the AR glasses 15 can display the clearance information by the AR display in the vicinity of the position where the clearance is present when the operator wears the AR glasses 15 and sees the vehicle. Therefore, the operator can recognize the clearance to be measured in a state in which the measurement is displayed on the AR glasses 15 and can measure the clearance and output the measurement result in a format of csv data or the like.

In this way, the needed information of the clearance to be measured is processed in association with the CAD data, and the position or the design value of the clearance is displayed using AR by the AR glasses, so that the position or the design value of the clearance can be easily presented to the operator.

As a result, it is easy to specify a place to be measured for a clearance from an entirety of the vehicle, and it is possible to shorten a time for searching for where a clearance to be measured is present, so that it is possible to improve work efficiency.

The present disclosure is not limited to the embodiment, and can be appropriately modified without departing from the spirit. That is, in the description, for clarification of the description, appropriate omissions and simplifications are made, and a person skilled in the art can easily change, add, or convert each element of the embodiment within the scope of the present disclosure.

The embodiment of the present disclosure can be implemented by hardware, a dedicated circuit, software, logic, or any combination thereof. Some aspects may be implemented in hardware, while other aspects may be implemented in firmware or software that may be executed by a controller, a microprocessor, or other computing device.

The present disclosure further provides at least one computer program product tangibly stored in non-transitory computer-readable storage medium. The computer program product includes computer-executable instructions, such as instructions included in a program module, and is executed on a target physical processor or a virtual processor to execute the process or method of the present disclosure. The program module includes a routine, a program, a library, an object, a class, a component, a data structure, or the like that executes a specific task or implements a specific abstract data type. The functions of the program modules may be combined or divided between the program modules as desired in various embodiments. The machine executable instructions of the program module can be executed in a local or distributed device. In the distributed device, the program module can be disposed on both the local storage medium and the remote storage medium.

The program code for executing the method of the present disclosure may be written in any combination of one or more programming languages. The program code is provided to a processor or a controller of a general-purpose computer, a dedicated computer, or another programmable data processing device. When the program code is executed by the processor or the controller, the function/operation in the flowchart, or the block diagram to be implemented, or both are executed. The program code is executed completely on a machine, a part of the program code is executed on the machine as a standalone software package, a part of the program code is executed on the machine, a part of the program code is executed on a remote machine, or the program code is executed completely on a remote machine or a server.

The program can be stored using various types of non-transitory computer-readable media and can be supplied to a computer. The non-transitory computer-readable medium includes various types of tangible recording media. Examples of the non-transitory computer-readable medium include a magnetic recording medium, an optical magnetic recording medium, an optical disk medium, and a semiconductor memory. Examples of the magnetic recording medium include a flexible disk, a magnetic tape, and a hard disk drive. Examples of the magneto-optical recording medium include a magneto-optical disk. Examples of the optical disk medium include a Blu-ray disc, a compact disc (CD)-read only memory (ROM), a CD-recordable (R), and a CD-rewritable (RW). Examples of the semiconductor memory include a solid state drive, a mask ROM, a programmable ROM (PROM), an erasable PROM (EPROM), a flash ROM, and a random access memory (RAM). In addition, the program may be supplied to the computer by various types of temporary computer-readable media. Examples of the transitory computer readable media include electrical signals, optical signals, and electromagnetic waves. The transitory computer readable medium can supply the program to the computer via a wired communication path, such as an electric wire and an optical fiber, or a wireless communication path.

What is claimed is:

1. A vehicle body clearance measurement support system that supports an operator in measuring a clearance of an overlapping portion of vehicle body parts, the vehicle body clearance measurement support system comprising:
a model provider configured to provide a CAD model;
a converter configured to convert information including a design value of the clearance into a format of digitally-processable data; and
an integrated output unit configured to associate the CAD model provided from the model provider, the digitally-processable data converted by the converter, and a shot diagram of a CAD of the clearance to be measured, and output position information of the clearance to be measured and information of the design value.

2. The vehicle body clearance measurement support system according to claim 1, further comprising a clearance information output unit configured to output report data in which clearance information used in practice is described,
wherein the converter is configured to execute a program for conversion on a report that is used in practice and is output from the clearance information output unit to convert the report into the digitally-processable data.

3. The vehicle body clearance measurement support system according to claim 2, wherein the converter is configured to extract solely the shot diagram of the CAD from the report used in practice output from the clearance information output unit, and generate a file in which information needed for measurement is summarized.

4. The vehicle body clearance measurement support system according to claim 1, further comprising a display unit configured to perform an AR display based on information input from the integrated output unit,
wherein the integrated output unit is configured to output information to the display unit in a state where an association is established with an area name of a vehicle to be measured set as a parent node and the clearance to be measured set as a child node.

5. The vehicle body clearance measurement support system according to claim 1, wherein the integrated output unit is configured to use a game engine.

6. A vehicle body clearance measurement support method comprising:
converting information including a design value of a clearance into a format of digitally-processable data; and
associating a CAD model, the digitally-processable data in the converting, and a shot diagram of a CAD of the clearance to be measured, and outputting position information of the clearance to be measured and the information of the design value.
